(19) United States
(12) Patent Application Publication
(10) Pub. No.: US 2005/0142773 A1
(43) Pub. Date: Jun. 30, 2005

(54) Structure and method for protecting substrate of an active area

(76) Inventors: Hsu-Li Cheng, Hsinchu City (TW); Jui-Hsiang Yang, Hsinchu City (TW)

Correspondence Address: BIRCH STEWART KOLASCH & BIRCH, PO BOX 747, FALLS CHURCH, VA, 22040-0747, US

(21) Appl. No.: 10/864,371

(22) Filed: Jun. 10, 2004

(30) Foreign Application Priority Data
Dec. 29, 2003 (TW) 092137315

(51) Int. Cl. H01L 21/336; H01L 29/76; H01L 29/94; H01L 31/062; H01L 31/113; H01L 31/119

(52) U.S. Cl. 438/296; 257/374

(57) ABSTRACT

A structure and method are provided for protecting a substrate of an active area adjacent to an isolation region. A substrate including an isolation region is provided, wherein a gate is disposed on the substrate adjacent to the isolation region. A sacrificial protective layer is deposited on the substrate and then etched back to form a sidewall protective layer on the sidewall of the gate, covering a portion of isolation region to protect the substrate adjoining the gate and the isolation region.

### BACKGROUND OF THE INVENTION

1. Field of the Invention

The present invention relates to IC fabrication technology and in particular to a structure and method for protecting an active area, particularly suitable for flash memory fabrication technology.

2. Description of the Related Art

There are two types of CMOS memory. The first is random access memory (RAM) and the second is read only memory (ROM). RAM is a volatile memory, in which data stored therein is lost when powered off. Data in ROM, however, remain stored when powered off. The applications for ROM are continually increasing with flash memory being particular invest to developers. Flash memory has gained popularity over EPROM and EEPROM because its memory cell is electrically programmable and erasable. Moreover, flash memory is less expensive than EPROM and EEPROM.

In a conventional fabrication method for split gate flash memory, an oxide layer in the STI region is easily etched during subsequent cleaning process, to a level lower than adjacent active area. Consequently, the active area is easily damaged without protection of the oxide layer in the STI region, resulting in undesirable leakage paths in the active area.

### SUMMARY OF THE INVENTION

Accordingly, an object of the invention is to provide a structure and method for protecting a substrate of an active area. The substrate of the active area is protected by a sidewall protective layer to prevent damage of the substrate of the active layer during subsequent etching process.

To achieve the above objects, the present invention provides a method for protecting a substrate of an active area, comprising the following steps. A substrate including an isolation region is provided, wherein a gate is disposed on the substrate adjacent to the isolation region. A sacrificial protective layer is deposited on the substrate and then etched back to form a sidewall protective layer on the sidewall of the gate, covering a portion of the isolation region to protect the substrate adjoining the gate and the isolation region.

The present invention provides a structure for protecting a substrate of an active area. A STI region is in a substrate. A gate is disposed on the substrate adjacent the STI region. A sidewall protective layer is disposed on sidewall of the gate, wherein the sidewall protective layer covers part of the STI region to protect the substrate adjacent to the intersection of the gate and the STI region.

A detailed description is given in the following embodiments with reference to the accompanying drawings.

### BRIEF DESCRIPTION OF THE DRAWINGS

The present invention can be better understood by reading the subsequent detailed description and examples with references made to the accompanying drawings, wherein:

FIG. 1G is a cross section of a conventional split gate flash memory, illustrating a damaged active area;

FIGS. 1A-1F schematically illustrate process steps for fabricating split gate flash memory;

FIGS. 2A-2H schematically illustrate process steps for fabricating split gate flash memory in accordance with the present invention; and

FIG. 2I is a cross section of the structure of the preferable embodiment for protecting substrate of an active area in accordance with the invention.

### DETAILED DESCRIPTION OF THE INVENTION

First Embodiment

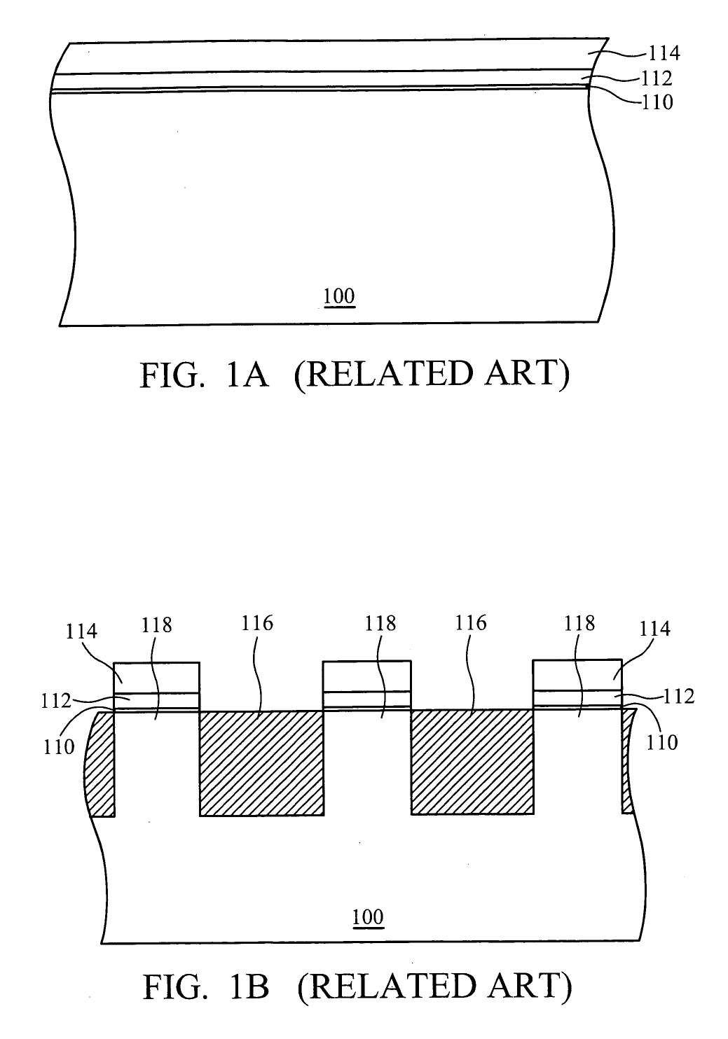

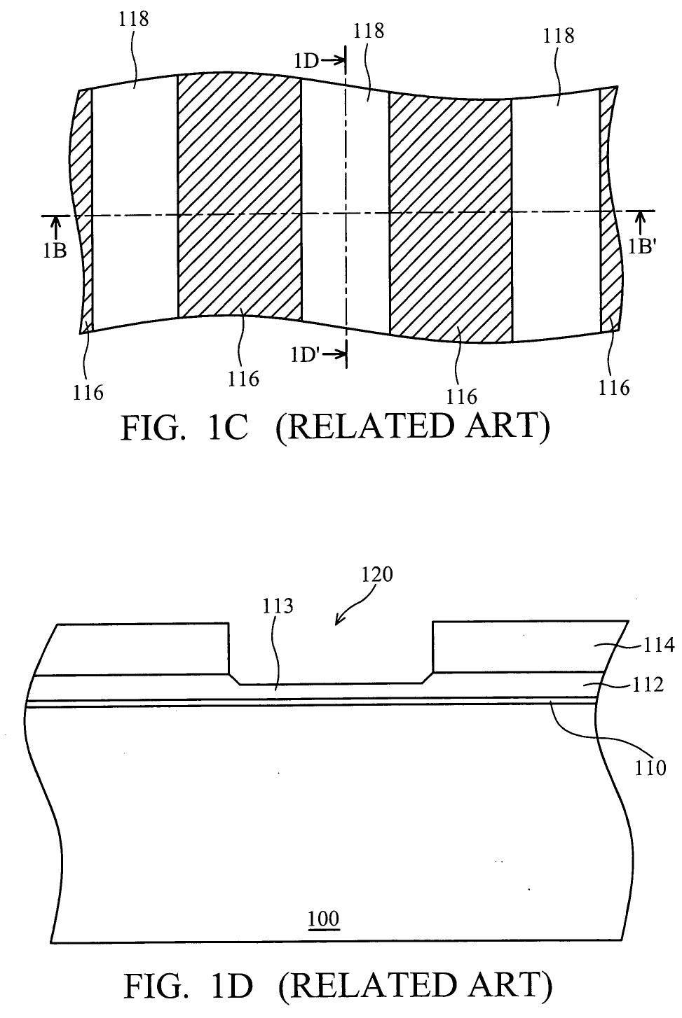

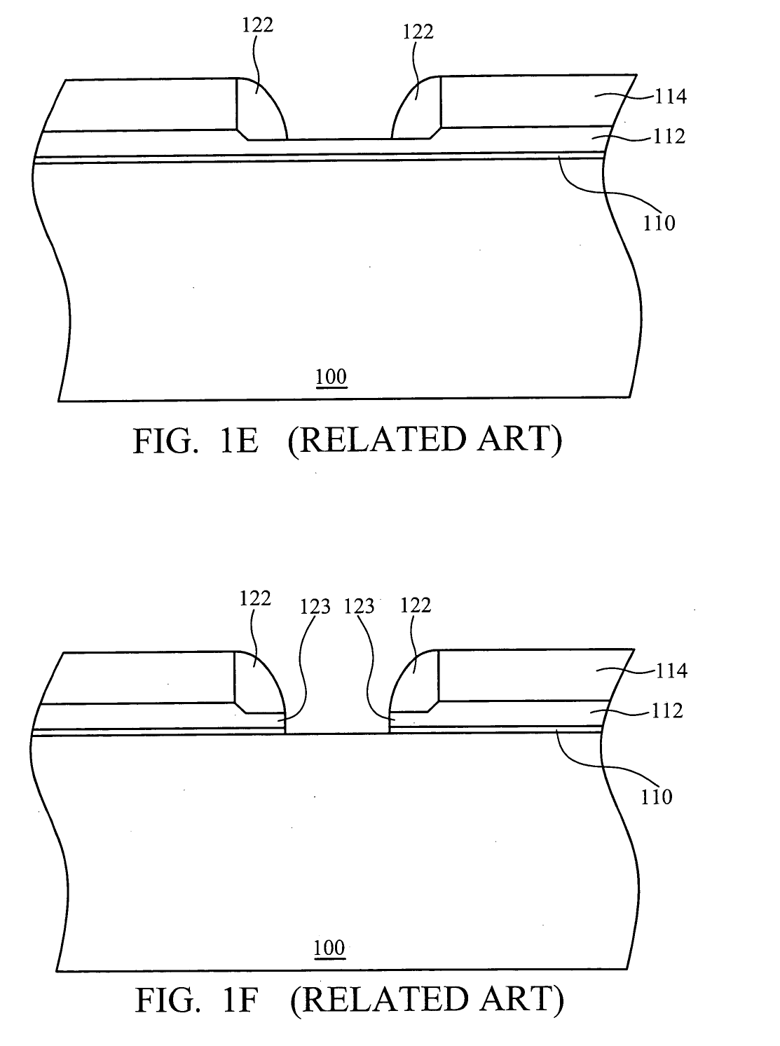

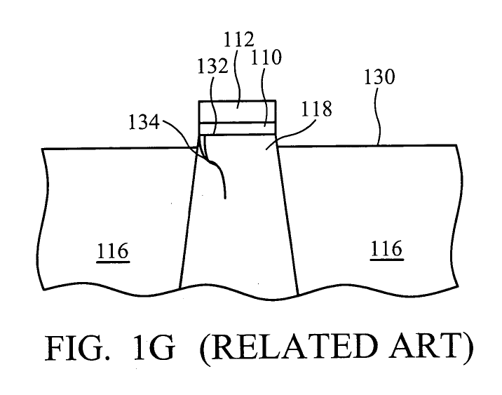

FIGS. 1A to 1G illustrate process steps for fabricating split gate flash memory known to the inventor. This is not prior art for the purpose of determining the patentability of the present invention. This merely shows a problem found by the inventor.

As shown in FIG. 1A, a substrate 100 is provided and followed by the formation of a gate dielectric layer 110 thereon. A floating gate layer 112 is formed on the gate dielectric layer 110, and a protective layer 114 is formed on the floating gate layer 112. As shown in FIG. 1B, a photoresist pattern is formed on the protective layer 214 (not shown). The protective layer 114, the floating gate layer 112, the gate dielectric layer 110 and the substrate 100 are etched in order using the photoresist pattern as a mask to form a plurality of first trenches 116. The photoresist pattern is then removed. The first trenches 116 are filled with oxide to form a plurality of STI. The plane view of the STI is shown in FIG. 1C, and FIG. 1B is a cross section along line 1B-1B′ of FIG. 1C.

Referring to FIG. 1D, another photoresist pattern is formed on the protective layer 214 (not shown). Referring to line 1D-1D′ of FIG. 1C, the protective layer 114, and a portion of the floating gate layer 113 on the active layer adjacent to the STI region are etched in order to form a second trench. The thin floating gate layer 113 below the second trench serves as a floating gate of a flash memory.

As shown in FIG. 1E, a dielectric layer is deposited and etched to form a sidewall dielectric layer 122 in the second trench 120. Referring to FIG. 1F, the floating gate layer 112 not protected by the protective layer 114 and the sidewall dielectric layer 122 is anisotropically etched, such that an ion implantation process proceeds on the exposed substrate 100 to form a source region and floating gate 123.

Referring to FIG. 1G, in the conventional fabrication method of split gate flash memory, the oxide layer in the STI region 116 is easily etched during subsequent cleaning process, such that the level 130 of the oxide layer is lower than the adjacent active area 132. Consequently, substrate 118 of the active area is easily damaged without protection of the oxide layer in the STI region 116, resulting in defects 134 of the active area as leakage paths.

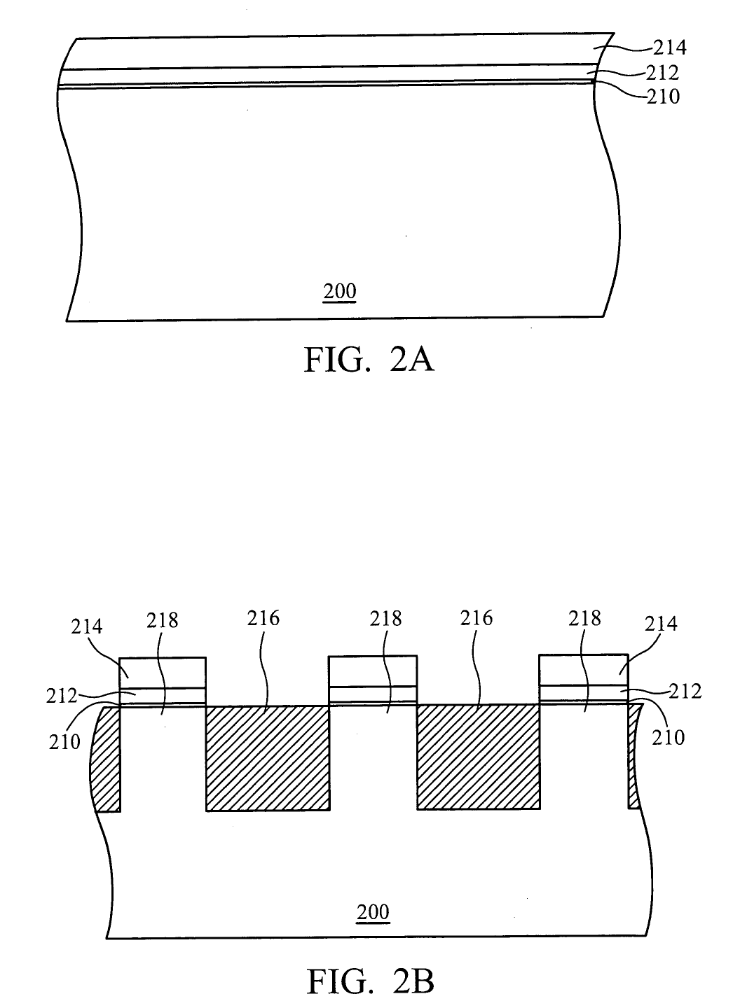

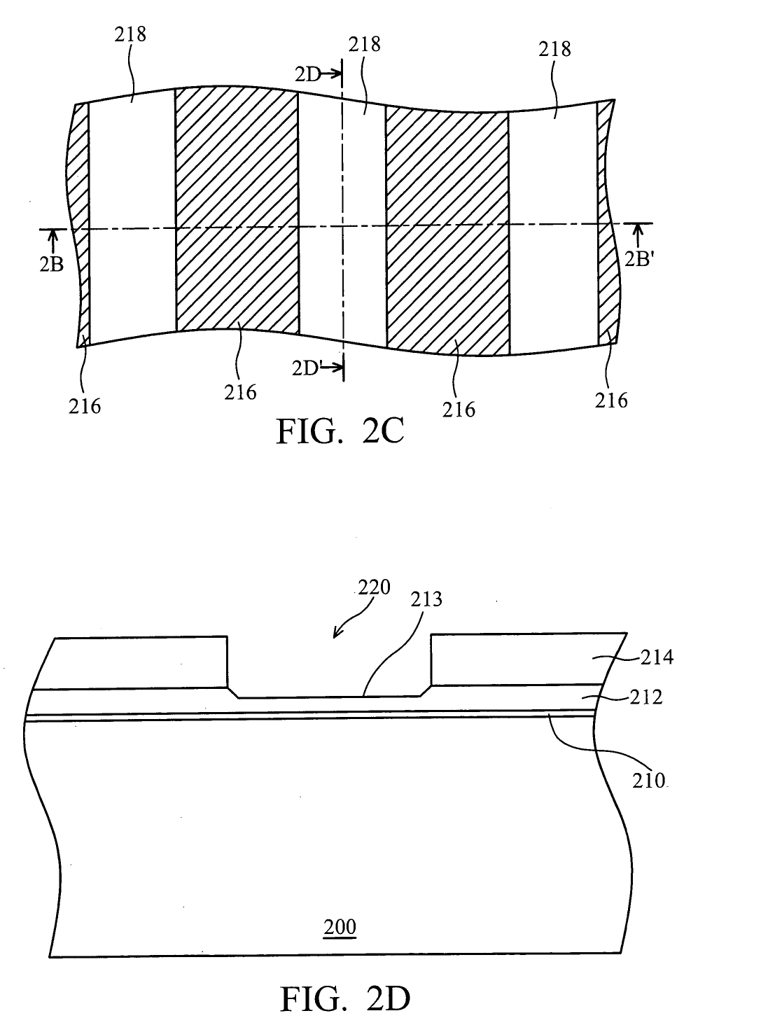

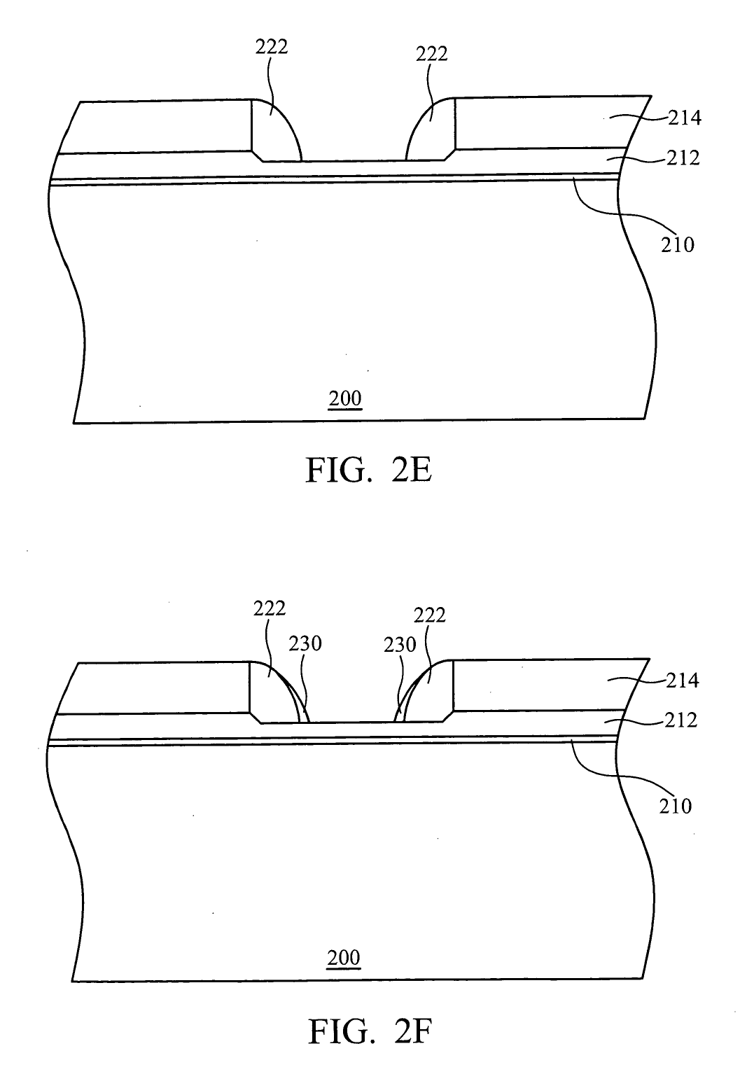

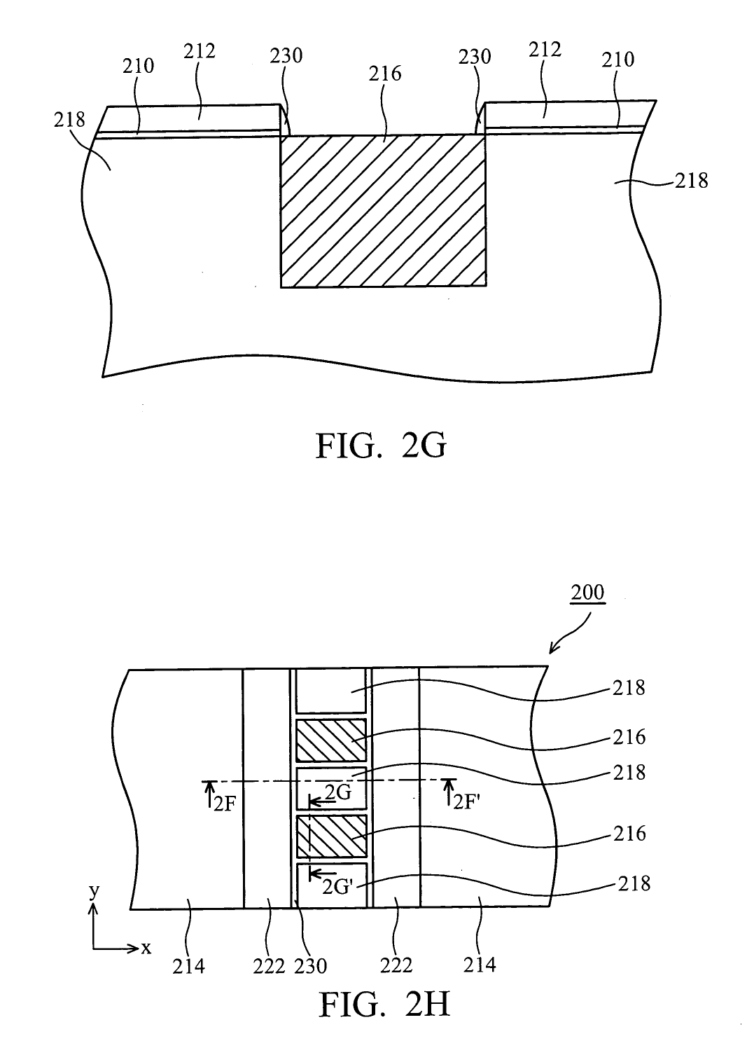

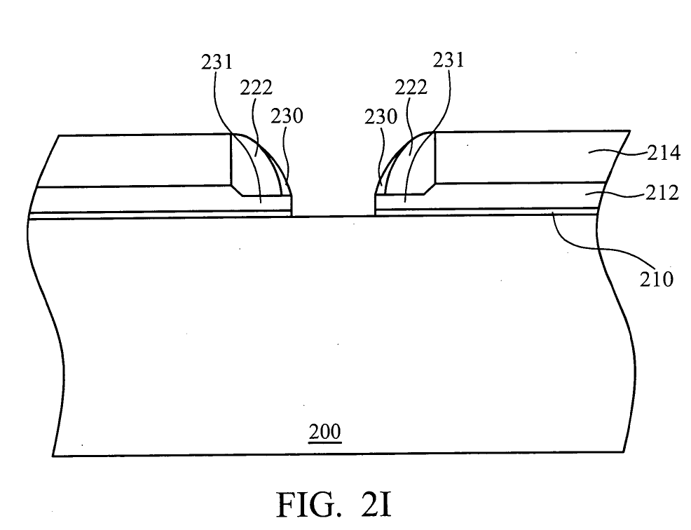

FIGS. 2A to 2I illustrate process steps in split gate flash memory in accordance with the present invention for protecting a substrate of an active area. FIG. 2H is a plane view of the method of the present invention.

As shown in FIG. 2A, a substrate 200 is provided and a gate dielectric layer 210 is formed subsequently thereon. Preferably, the substrate 200 is a silicon substrate and the gate dielectric layer 210 is formed by thermal oxidation. A floating gate layer 212 is formed on the gate dielectric layer 210, and a protective layer 214 is formed on the floating gate layer 212. Preferably, the floating gate layer 212 is polysilicon and the protective layer 214 is silicon nitride. As shown in FIG. 2B, a photoresist pattern is formed on the protective layer 214 (not shown). The protective layer 214, the floating gate layer 212, the gate dielectric layer 210 and the substrate 200 are etched in order using the photoresist pattern as a mask to form a plurality of first trenches 216, followed by removal of the photoresist pattern thereof. The first trenches 216 are filled with an insulating layer, such as oxide, to form a plurality of STIs. A plane view of the STI is shown in FIG. 2C, and FIG. 2B is a cross section along line 2B-2B′ of FIG. 2C.

As shown in FIG. 2D, another photoresist pattern is formed on the protective layer 214 (not shown). Referring to line 2D-2D′ of FIG. 2C, the protective layer 214 and a portion of the floating gate layer 212 on the active area 218 adjacent to the STI region are etched in order to form a second trench 220. The thin floating gate layer below the second trench serves as a floating gate of a flash memory.

As shown in FIG. 2E, a dielectric layer, such as oxide or nitride, is deposited and etched to form a sidewall dielectric layer 222 in the second trench. The preferable thickness of the sidewall dielectric layer 222 is 2000 Å˜3000 Å.

Referring to FIG. 2F, a sacrificial protective layer (not shown), preferably formed of TEOS, nitride or silicon oxide nitride with a thickness of 500 Å-800 Å, is deposited on the substrate. The sacrificial protective layer is anisotropically etched to form a sidewall protective layer 230 on the sidewall of the sidewall dielectric layer 222, in which CF4, C2F6 or CH3 is chosen as a processing gas with plasma reaction. The sidewall protective layer 230 preferably has a width of 100 Å-600 Å. As shown in FIG. 2G, sidewall protective layer 230 is also formed on sidewall of the floating gate layer 212, wherein the sidewall protective layer 230 covers part of STI region 216 to protect the substrate 218 adjacent to the intersection of the gate 212 and the STI region 216. FIG. 2H shows top view of the active area and STI region. FIG. 2F is a cross section along line 2F-2F′ of FIG. 2H. FIG. 2G is a cross section along line 2G-2G′ of FIG. 2H.

Referring to FIG. 2I, the floating gate layer 212, not protected by the protective layer 230 and the sidewall dielectric layer 222, is etched anisotropically to form floating gates 231. Preferably, Cl₂ is used as an etching gas with plasma reaction. Additionally, an ion implantation process proceeds on the exposed substrate 200 to form a source region.

As shown in FIG. 2G, the substrate 218 between two STI regions is protected by sidewall protective layer 230, preventing damage to the substrate 218.

Referring to FIG. 2F, FIG. 2G, and FIG. 2H, a plurality of STI regions 216 are disposed in a substrate 200. The STI region 216 is a trench filled with oxide, and the substrate adjacent to the STI region in Y orientation is referred to as an active area 218. A gate dielectric layer 210, preferably formed of silicon oxide, is disposed on the active area. A gate 212, preferably formed of polysilicon, is disposed thereon. A sidewall dielectric layer 222 and protective layer 214 are disposed on the substrate adjacent the STI region in the X orientation. Preferable thickness of the gate dielectric layer 222 is 2000 Å˜3000 Å.

A sidewall protective layer 230 is disposed on the sidewall of the gate 212 and the gate dielectric layer 222 to protect the active area. The sidewall protective layer 230 covers part of STI region 216 to protect the substrate adjacent the cross of gate and STI region, such that the active area 218 will not be damaged in the subsequent etching process. The sidewall protective layer 222 is preferably formed of silicon oxide, silicon nitride, or silicon oxide nitride.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for protecting a substrate of an active area, comprising the following steps:
providing a substrate including a STI region, wherein a gate is disposed on the substrate adjacent to the STI region;
depositing a sacrificial protective layer on the substrate; and
etching the sacrificial protective layer to form a sidewall protective layer on a sidewall of the gate, wherein the sidewall protective layer covers part of the STI region to protect the substrate adjacent to the intersection of the gate and the STI region.

2. The method as claimed in claim 1, wherein the STI region is formed of silicon oxide.

3. The method as claimed in claim 1, further comprising a gate dielectric layer between the gate and the substrate.

4. The method as claimed in claim 3, wherein the gate dielectric layer is silicon oxide.

5. The method as claimed in claim 1, wherein the sidewall protective layer is silicon oxide, silicon nitride, or silicon oxide nitride.

6. The method as claimed in claim 1, wherein the step of etching the sacrificial protective layer is anisotropically etching the sacrificial protective layer.

7. A method for protecting a substrate of an active area, comprising the following steps:
providing a substrate, wherein a gate dielectric layer is formed on the substrate, a floating gate layer is formed on the gate dielectric layer, and a protective layer is formed on the floating gate layer;
pattering the protective layer, the floating gate layer, the gate dielectric layer and the substrate in order along the second orientation to form a plurality of first trenches;
filling the first trenches with an insulating layer to form a plurality of STI regions;
patterning a protective layer and part of the floating gate layer on the substrate adjacent to the STI regions along the first orientation to form a plurality of second trenches;
forming a sidewall dielectric layer on the sidewall of the second trenches;
depositing a sacrificial protective layer on the substrate;
etching the sacrificial protective layer to form a sidewall protective layer on a sidewall of the floating gate layer, and the sidewall dielectric layer; and
etching the floating gate layer and the gate dielectric layer with the sidewall dielectric layer wherein the protective layer serves as a mask.

8. The method as claimed in claim 7, wherein the first direction and the second direction are perpendicular.

9. The method as claimed in claim 7, wherein the floating gate layer is polysilicon.

10. The method as claimed in claim 7, wherein the gate dielectric layer is silicon oxide.

11. The method as claimed in claim 7, wherein the sidewall dielectric layer is silicon oxide.

12. The method as claimed in claim 7, wherein the sidewall protective layer is silicon oxide, silicon nitride, or silicon oxide nitride.

13. The method as claimed in claim 7, wherein etching the sacrificial protective layer is anisotropically etching the sacrificial protective layer.

14. A structure for a protecting substrate for an active area, comprising:
a substrate;
a STI region in the substrate;
a gate disposed on the substrate adjacent to the STI region; and
a sidewall protective layer disposed on a sidewall of the gate, wherein the sidewall protective layer covers part of the STI region to protect the substrate adjacent to the intersection of the gate and the STI region.

15. The structure as claimed in claim 14, wherein the sidewall protective layer has a width of 100 Å-600 Å.

16. The structure as claimed in claim 14, wherein the gate includes a gate dielectric layer on the substrate, and a floating gate layer on the gate dielectric layer.

17. The structure as claimed in claim 16, wherein the gate dielectric layer is silicon oxide.

18. The structure as claimed in claim 14, wherein the sidewall protective layer is silicon oxide, silicon nitride, or silicon oxide nitride.
